(19) United States
(12) Patent Application Publication
(10) Pub. No.: US 2008/0296667 A1
(43) Pub. Date: Dec. 4, 2008

(54) Semiconductor device and manufacturing method thereof

(75) Inventor: Noriaki Mikasa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/153,971

(22) Filed: May 28, 2008

(30) Foreign Application Priority Data
May 29, 2007 (JP) 2007-141395

(51) Int. Cl. H01L 29/00; H01L 21/336

(52) U.S. Cl. 257/327; 438/268; 257/E29.001; 257/E21.409

(57) ABSTRACT

A semiconductor device includes a fin active region with a tapered side surface, a gate electrode that has a side surface covering portion covering a part of the side surface of the fin active region and a top surface covering portion covering a part of a top surface of the fin active region, and a source region and drain region formed in the fin active region. In at least a part of the side surface covering portion of the gate electrode, the width is wider at its bottom than at its top. Control of electric field by the gate electrode is improved. Punch-through is thus prevented.

### TECHNICAL FIELD

The present invention relates to a semiconductor device and a manufacturing method thereof, and, more particularly relates to a semiconductor device having a fin field effect transistor and a manufacturing method thereof.

### BACKGROUND OF THE INVENTION

In recent years, along with miniaturization of DRAM (Dynamic Random Access Memory) cells, the gate length of a memory cell transistor needs to be shortened and the channel width needs to be made narrower. However, as the channel width becomes narrower, the channel resistance of the transistor is increased considerably, resulting in a decrease in drive current.

As a technique for preventing such a problem, fin field effect transistors have attracted attention that a narrow active region is formed like a fin in a direction perpendicular to a semiconductor substrate and a gate electrode is placed around the active region (see Japanese Patent Application National Publication No. 2005-528810, Japanese Patent Application Laid-open Nos. 2002-110963 and 2005-64500). According to such fin field effect transistors, as compared to planar transistors, the operating speed and on current are expected to be increased and the power consumption is expected to be reduced.

However, when the fin field effect transistor is formed, the cross-section of the fin active region may be formed in a trapezoidal shape other than a rectangular or square shape because of processing problems. For example, assume that a fin active region and a trench for STI (Shallow Trench Isolation) are formed by the same process. If the side surface of the STI is tapered to improve an embedding property of an insulating film to be embedded in the shallow trench, the side surface of the fin active region is also tapered. The cross-section of the fin active region is thus formed in a trapezoidal shape.

In the case of the fin active region with the trapezoidal cross-section, the width of the fin active region becomes narrow toward its top and wide toward its bottom. Accordingly, at the bottom of the fin active region with wide width, control of electric field by a gate electrode is decreased. An area where the electric field cannot reach may be formed within a channel. Punch-through thus occurs between a source region and a drain region formed in the fin active region.

To avoid these problems, it is conceivable to reduce the width of the fin active region on the whole in order to improve the control of electric field. However, if the width of the fin active region is reduced on the whole, the area of a top surface of the fin active region is reduced correspondingly. A source contact and a drain contact are thus difficult to be formed. If the width of the fin active region is further reduced, the cross-section finally becomes a triangular shape. The height of the fin active region is reduced and desired characteristics cannot be obtained.

Alternatively, it is also conceivable to make the gate electrode wider on the whole in order to physically increase the distance between the source region and the drain region. However, if the gate electrode is made wider, the area of the top surface of the fin active region covered by the gate electrode is increased. The area that the source contact and the drain contact can be formed is reduced correspondingly. A margin for forming the source contact and the drain contact is reduced and short circuits between the gate electrode and the source and the drain contacts easily occur.

### SUMMARY OF THE INVENTION

The present invention has been achieved to solve the above problems. An object of the present invention is to provide an improved semiconductor device that the cross-section of a fin active region is formed in a trapezoidal shape, and a manufacturing method thereof.

Another object of the present invention is to provide a semiconductor device that the cross-section of the fin active region is formed in a trapezoidal shape and control of electric field at the bottom of the fin active region is improved, and a manufacturing method thereof.

Still another object of the present invention is to provide a semiconductor device that the cross-section of the fin active region is formed in a trapezoidal shape and punch-through is prevented while the area of a top surface of the fin active region is ensured, and a manufacturing method thereof.

Still another object of the present invention is to provide a semiconductor device that the cross-section of the fin active region is formed in a trapezoidal shape and punch-through is prevented while the height of the fin active region is ensured, and a manufacturing method thereof.

Still another object of the present invention is to provide a semiconductor device that the cross-section of the fin active region is formed in a trapezoidal shape and punch-through is prevented while a margin for forming a source contact and a drain contact is ensured, and a manufacturing method thereof.

The semiconductor device according to the present invention includes: a fin active region having a tapered side surface; a gate electrode that has a side surface covering portion covering a part of the side surface of the fin active region and a top surface covering portion covering a part of a top surface of the fin active region; and a source region and a drain region formed in the fin active region, a width of at least a part of the side surface covering portion of the gate electrode is wider at its relatively lower part than at its relatively upper part.

The method of manufacturing a semiconductor device according to the present invention includes: forming a fin active region with a tapered cross-section; forming a gate electrode that has a side surface covering portion covering a part of the side surface of the fin active region and a top surface covering portion covering a part of a top surface of the fin active region; and performing ion implantation into the fin active region using the gate electrode as a mask to form a source region and a drain region in the fin active region, wherein at least a part of a distance between the source region and the drain region is longer at relatively lower part of the fin active region than at relatively upper part of the fin active region.

According to the present invention, in at least a part of the side surface covering portion of the gate electrode, the width is wider at its bottom than at its top. Control of electric field at the bottom of the fin active region is improved. Punch-through can be thus prevented.

Because the width of the fin active region does not need to be totally reduced, the area of the top surface of the fin active region can be sufficiently obtained. Accordingly, a source contact and a drain contact can be formed easily. In addition, as the height of the fin active region is not shortened, desired characteristics can be obtained.

Further, because the area of the top surface of the fin active region covered by the gate electrode is small, the area that the source contact and the drain contact can be formed is ensured sufficiently. Accordingly, a margin for forming the source contact and the drain contact is ensured sufficiently, and short circuits between the gate electrode and the source and drain contacts are thus prevented.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic perspective view for explaining the configuration of a semiconductor device according to a first embodiment of the present invention;

FIGS. 2A and 2B are schematic exploded perspective views of the semiconductor device shown in FIG. 1;

FIGS. 3A and 3B are exploded perspective views of the fin active region 13 as disassembled source region 15, the drain region 16, and a channel region 17;

FIGS. 4A to 4D show a process (for forming a hard mask 101) in a manufacturing method of the semiconductor device according to the first embodiment;

FIGS. 5A to 5D show a process (for forming a trench 102) in the manufacturing method of the semiconductor device according to the first embodiment;

FIGS. 6A to 6D show a process (for forming an STI 103) in the manufacturing method of the semiconductor device according to the first embodiment;

FIGS. 7A to 7D show a process (for forming a gate insulating film 105) in the manufacturing method of the semiconductor device according to the first embodiment;

FIGS. 8A to 8D show a process (for forming a DOPOS (Doped Polysilicon) film 106) in the manufacturing method of the semiconductor device according to the first embodiment;

FIGS. 9A to 9D show a process (for forming a hard mask 107) in the manufacturing method of the semiconductor device according to the first embodiment;

FIGS. 10A to 10D show a process (for etching the DOPOS film 106 as a first step) in the manufacturing method of the semiconductor device according to the first embodiment;

FIGS. 11A to 11D show a process (for forming gate electrode 108 by etching the DOPOS film 106 as a second step) in the manufacturing method of the semiconductor device according to the first embodiment;

FIGS. 12A to 12D show a process (for forming a source region 109 and a drain region 110) in the manufacturing method of the semiconductor device according to the first embodiment;

FIG. 13 is a schematic perspective view for explaining the configuration of a semiconductor device according to a second embodiment of the present invention;

FIGS. 14A to 14D show a process (for forming a hard mask 201) in a manufacturing method of the semiconductor device according to the second embodiment;

FIGS. 15A to 15D show a process (for forming a trench 202) in the manufacturing method of the semiconductor device according to the second embodiment;

FIGS. 16A to 16D show a process (for forming an STI 203) in the manufacturing method of the semiconductor device according to the second embodiment;

FIGS. 17A to 17D show a process (for forming a hard mask 205) in the manufacturing method of the semiconductor device according to the second embodiment;

FIGS. 18A to 18D show a process (for etching the STI 103) in the manufacturing method of the semiconductor device according to the second embodiment;

FIGS. 19A to 19D show a process (for forming a side wall 206) in the manufacturing method of the semiconductor device according to the second embodiment;

FIGS. 20A to 20D show a process (for forming a groove 207) in the manufacturing method of the semiconductor device according to the second embodiment;

FIGS. 21A to 21D show a process (for removing the hard mask 205 and the side wall 206) in the manufacturing method of the semiconductor device according to the second embodiment;

FIGS. 22A to 22D show a process (for forming gate insulating film 208) in the manufacturing method of the semiconductor device according to the second embodiment;

FIGS. 23A to 23D show a process (for forming a DOPOS film 209) in the manufacturing method of the semiconductor device according to the second embodiment;

FIGS. 24A to 24D show a process (for forming a hard mask 210) in the manufacturing method of the semiconductor device according to the second embodiment;

FIGS. 25A to 25D show a process (for forming a gate electrode 211) in the manufacturing method of the semiconductor device according to the second embodiment; and

FIGS. 26A to 26D show a process (for forming a source region 212 and drain region 213) in the manufacturing method of the semiconductor device according to the second embodiment.

### DETAILED DESCRIPTION OF THE EMBODIMENTS

Preferred embodiments of the present invention will be explained below in detail with reference to the accompanying drawings.

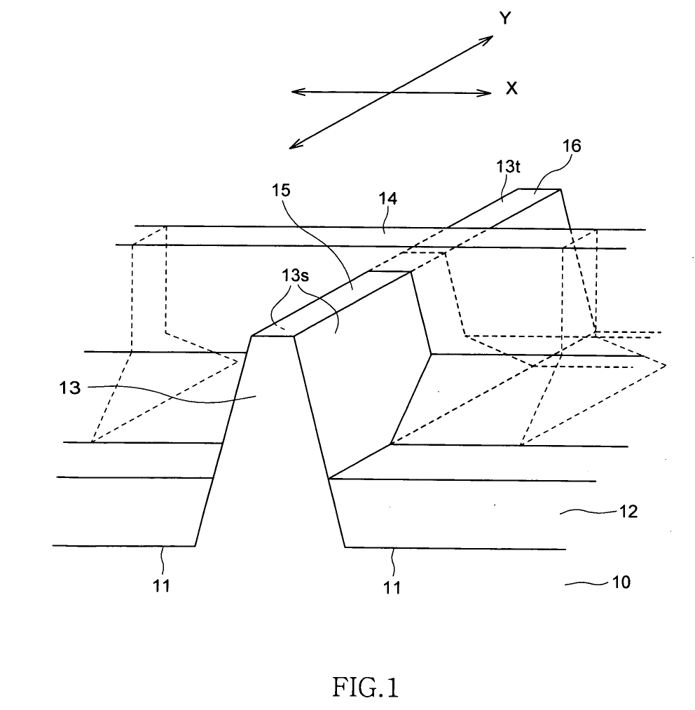

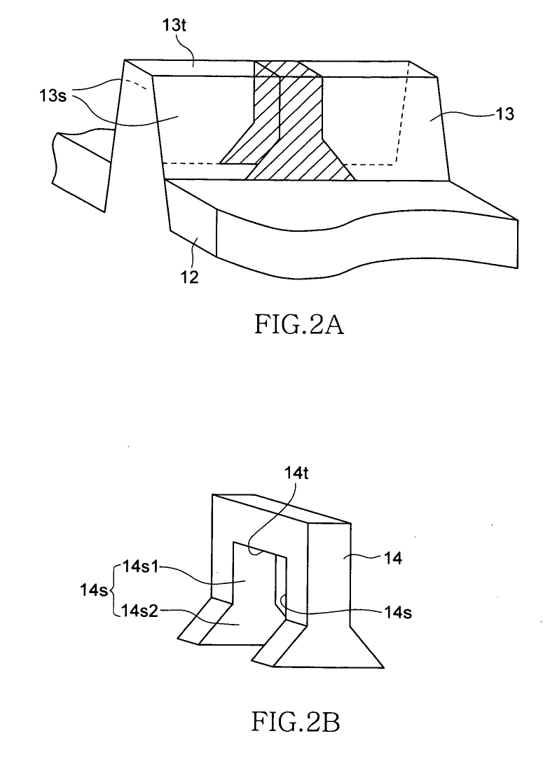

FIG. 1 is a schematic perspective view for explaining the configuration of a semiconductor device according to a first embodiment of the present invention. FIGS. 2A and 2B are schematic exploded perspective views of the semiconductor device shown in FIG. 1.

As shown in FIG. 1, the semiconductor device according to the first embodiment has a semiconductor substrate 10, a trench 11 formed in the semiconductor substrate 10, and an STI 12 provided on the bottom of the trench 11. The STI 12 is embedded in the trench 11 from the bottom to the middle of the trench. A fin portion which is a part of the semiconductor substrate protruding upward from the STI 12 serves as a fin active region 13. The fin active region 13 extends in the Y direction shown in FIG. 1 and has a top surface 13t and two side surfaces 13s. The side surfaces 13s of the fin active region 13 are in the same planes as those of the STI 12.

As shown in FIG. 1, because the side surfaces 13s of the fin active region 13 are tapered, the cross-section of the fin active region 13 is formed in a trapezoidal shape. The cross-section of the fin active region 13 means a cross-section along the X direction shown in FIG. 1. The fin active region 13 with such cross-section is provided because the fin active region 13 and the trench 11 are formed in the same process. To improve embedding of an insulating film into the STI, the side surface of the STI 12 (=side surface of trench 11) must be tapered. When the fin active region 13 and the trench 11 are formed in the same process, the side surface 13s of the fin active region 13 is formed inevitably in a tapered shape.

Because the cross-section of the fin active region 13 is thus a trapezoidal shape, the width of the fin active region 13 in the X direction becomes narrower toward its top and wider toward its bottom.

Further, the semiconductor device according to the first embodiment has a gate electrode 14 extending in the X direction so as to cross the fin active region 13. Parts of the side surfaces 13s and the top surface 13t of the fin active region 13 are covered by the gate electrode 14. As described below, a source region 15 and a drain region 16 are formed in the fin active region so as to sandwich the gate electrode 14. A fin field effect transistor is thus configured.

As shown in FIG. 1, the Y direction width of the gate electrode 14 is substantially fixed in the top area, but in the bottom area, wider toward the semiconductor substrate 10. Specifically, the inner side surface of the gate electrode 14 includes, as shown in FIG. 2B, a side surface covering portion 14s covering a part of the side surface 13s of the fin active region 13 and a top surface covering portion 14t covering a part of the top surface 13t. With reference to FIG. 2A, the parts of the side surface 13s and the top surface 13t of the fin active region 13 corresponding to the side surface covering portion 14s and the top surface covering portion 14t of the gate electrode 14 are hatched.

The side surface covering portion 14s includes a non-tapered portion 14s1 with substantial fixed Y direction width and a tapered portion 14s2 whose Y direction width becomes wider from the top to the bottom as shown in FIG. 2A. The Y direction width of the non-tapered portion 14s1 substantially coincides with that of the top surface covering portion 14t.

In the non-tapered portion 14s1, the Y direction width of the gate electrode 14 is fixed regardless of the X direction width of the fin active region 13. In the tapered portion 14s2, the wider the X direction width of the fin active region 13 becomes, the wider the Y direction width of the gate electrode 14. Although the X direction width of the bottom of the fin active region 13 is wide, the Y direction width of the gate electrode 14 is increased correspondingly, so that control of electric field by the gate electrode 14 is improved. Punch-through between the source region 15 and the drain region 16 is thus suppressed.

Further, on the top surface 13t of the fin active region 13, the gate electrode 14 is narrow, i.e., has substantially the same width as that of upper part 14s2 of the side surface covering portion 14s. A short margin between the gate electrode 14 and a source contact or a drain contact (not shown) formed on the both adjacent sides of the gate electrode 14 is sufficiently ensured.

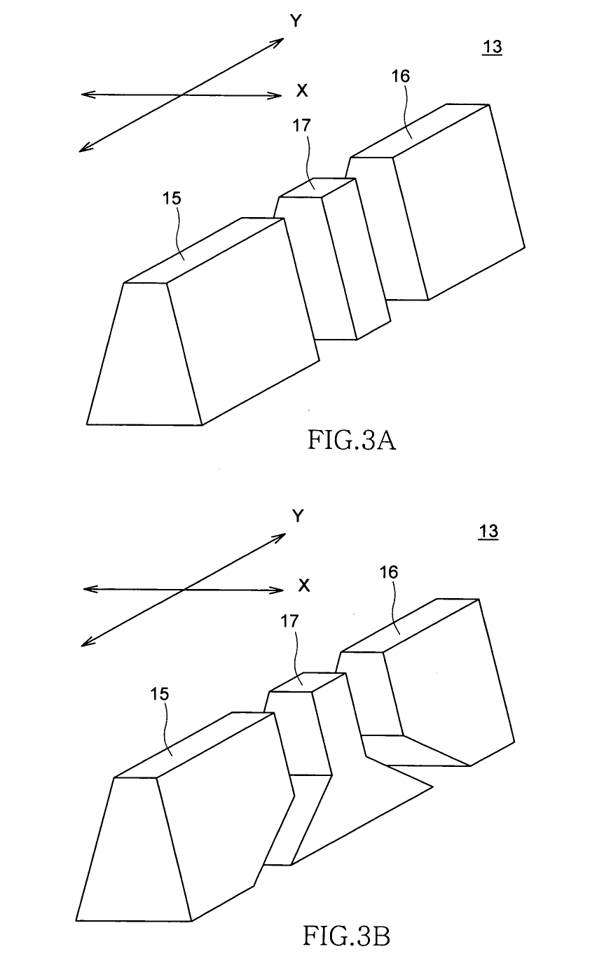

FIGS. 3A and 3B are exploded perspective views of the fin active region 13 as disassembled source region 15, the drain region 16, and a channel region 17. FIG. 3A shows a first example and FIG. 3B shows a second example.

In the example shown in FIG. 3A, the Y direction width of the channel region 17, i.e., the distance between the source region 15 and the drain region 16 is substantially fixed from the top to the bottom of the fin active region 13. The distance between the source region 15 and the drain region 16 coincides substantially with the width of the top surface covering portion 14t of the gate electrode 14. Such a configuration is provided by performing ion implantation in a direction vertical to the semiconductor substrate 10 by using the gate electrode 14 as a mask.

In the configuration shown in FIG. 3A, punch-through occurs easily at the bottom of the fin active region 13. According to the first embodiment, however, at the bottom of the fin active region 13, as the X direction width of the fin active region 13 is increased, the Y direction width of the gate electrode 14 is also increased. Punch-through is thus prevented.

Meanwhile, according to the example of FIG. 3B, the Y direction width of the channel region 17, i.e., the distance between the source region 15 and the drain region 16 corresponds to the Y direction width of the gate electrode 14. In at least a part of the fin active region 13, the distance between the source region 15 and the drain region 16 is larger at the bottom of the fin active region 13 than at its top. This configuration is realized by performing ion implantation in an oblique direction to the semiconductor substrate 10 with the gate electrode 14 being utilized as a mask. Specifically, ion implantation is performed upon one side surface 13s and then the other side surface 13s of the fin active region 13. The shapes of the source region 15 and the drain region 16 reflect the shape of the gate electrode 14.

According to the configuration of FIG. 3B, at the bottom of the fin active region 13, as the X direction width of the fin active region 13 is increased, the distance between the source region 15 and the drain region 16 is also increased, so that punch-through hardly occurs. Additionally, in the first embodiment, as the X direction width of the fin active region 13 is increased, the Y direction width of the gate electrode 14 is also increased at the bottom of the fin active region 13. Punch-through is thus prevented more effectively.

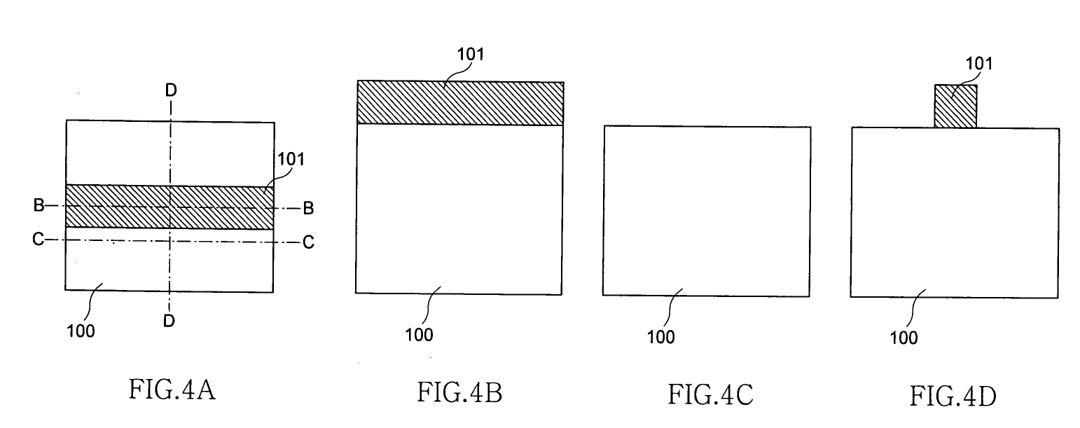

A method for manufacturing the semiconductor device according to the first embodiment is described next with reference to FIGS. 4A to 12D. In FIGS. 4A to 12D, the drawings with alphabetical letter A attached with their respective numbers are top views, and the drawings with alphabetical letters B, C, and D attached with their respective numbers are cross-sectional views along the lines B-B, C-C, and D-D, respectively. The line D-D corresponds to the X direction in FIG. 1, while the lines B-B and C-C the Y direction in FIG. 1.

First, as shown in FIGS. 4A to 4D, a hard mask 101 for covering an area on a semiconductor substrate 100 which is to be a fin active region is formed. Silicon nitride is preferably used for material of the hard mask 101.

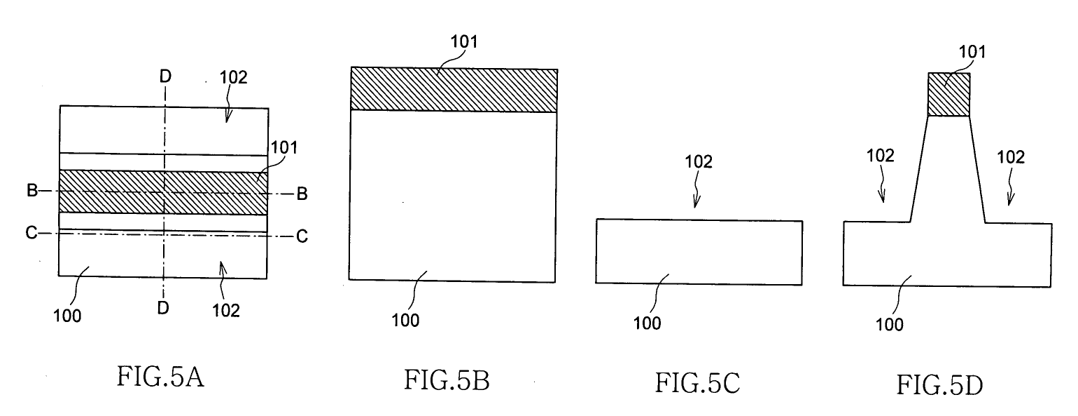

Next, as shown in FIGS. 5A to 5D, the semiconductor substrate 100 is etched using the hard mask 101 to form a trench 102 with a depth of about 250 nm. Because the trench 102 is provided for STI, the semiconductor substrate 100 is etched not vertically but in a manner to provide a predetermined taper. As shown in FIG. 5D, the cross-section of the semiconductor substrate 100 along the line D-D is formed in a trapezoidal shape.

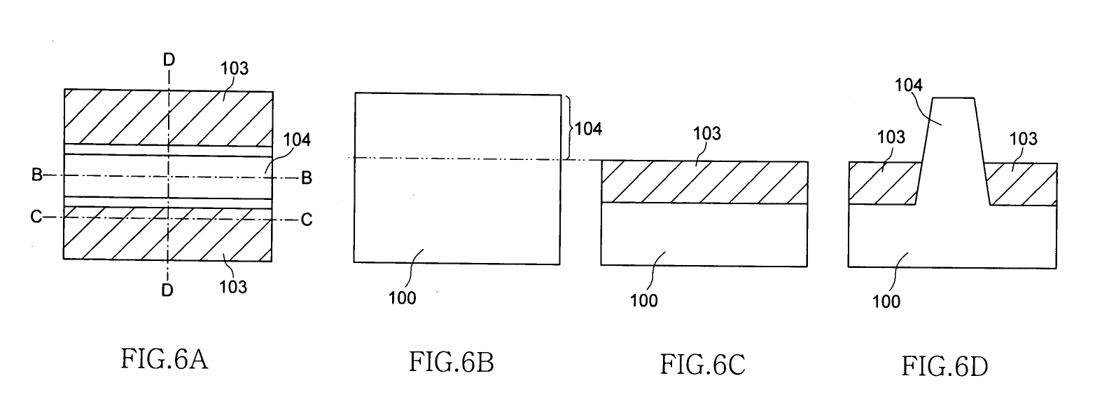

Silicon oxide is then applied entirely, and the silicon oxide on the top of the substrate is then removed by wet etching. As shown in FIGS. 6A to 6D, an STI 103 with a thickness of about 100 nm is formed on the bottom of the trench 102. A part of the semiconductor substrate 100 protruding from the STI 103 serves as a fin active region 104 with a height of, e.g., about 150 nm. The cross-section of the fin active region 104 is formed in a trapezoidal shape.

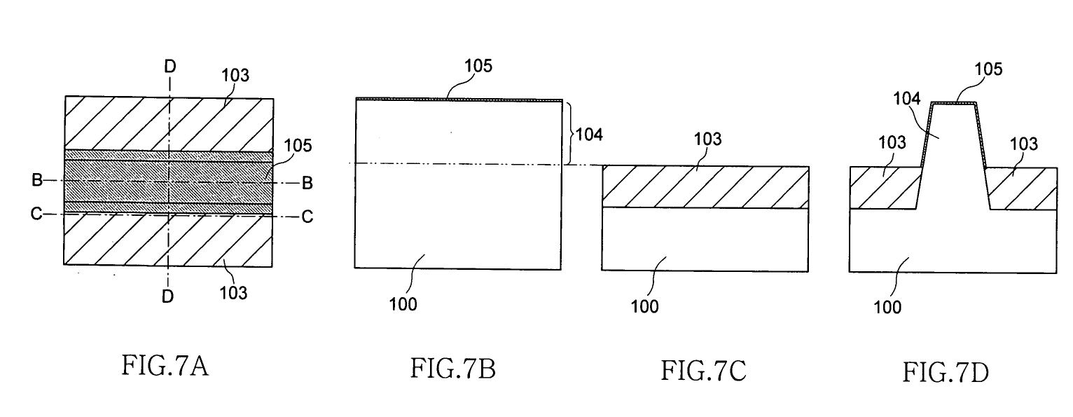

As shown in FIGS. 7A to 7D, a gate insulating film 105 is then applied on the surface (top and side surfaces) of the fin active region 104.

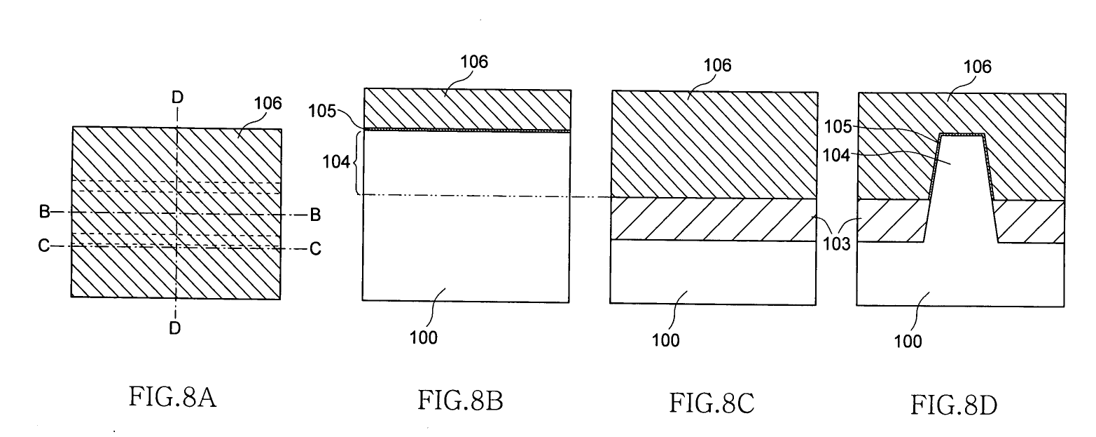

Next, as shown in FIGS. 8A to 8D, a DOPOS (Doped Polysilicon) film 106 is applied entirely. CMP (Chemical Mechanical Polishing) is then performed for flattening so that the thickness of the film 106 on the gate insulating film 105 is about 100 nm.

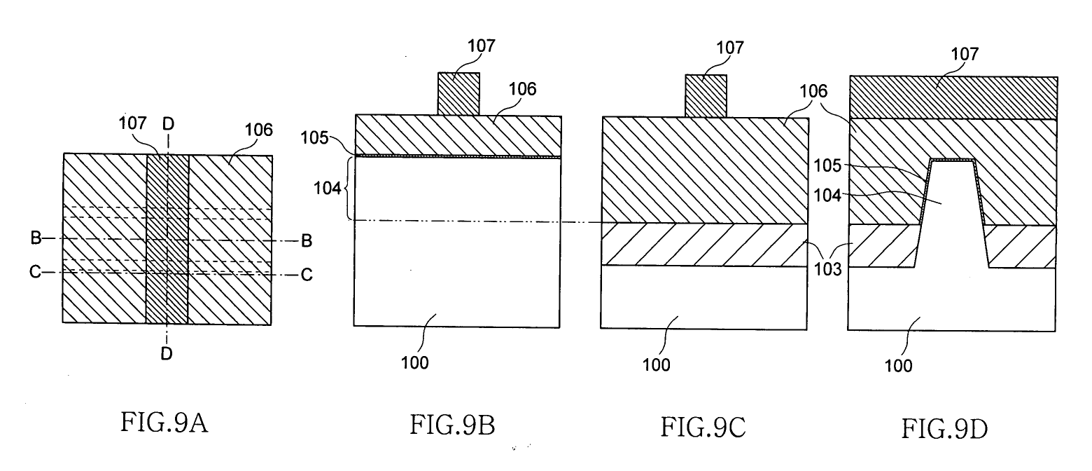

As shown in FIGS. 9A to 9D, a hard mask 107 that is made of silicon nitride and has a width of about 100 nm is then formed on the DOPOS film 106 for forming a gate electrode.

The DOPOS film 106 is dry etched in the pattern of the gate electrode by using the hard mask 107. This process is performed by two steps as follows.

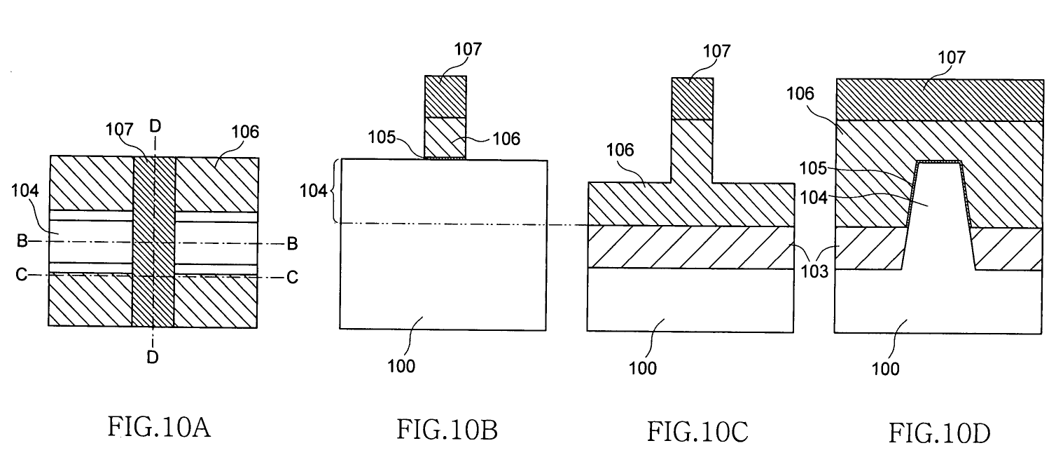

At a first step, as shown in FIGS. 10A to 10D, the DOPOS film 106 is etched vertically using a mixed gas of HBr gas, O₂ gas, and SF₆gas until at least the surface of the fin active region 104 is exposed. For example, when the thickness of the DOPOS film 106 on the gate insulating film 105 is about 100 nm, the DOPOS film 106 is etched about 150 nm. The remaining DOPOS film 106 that is not subjected to etching has a thickness of about 100 nm.

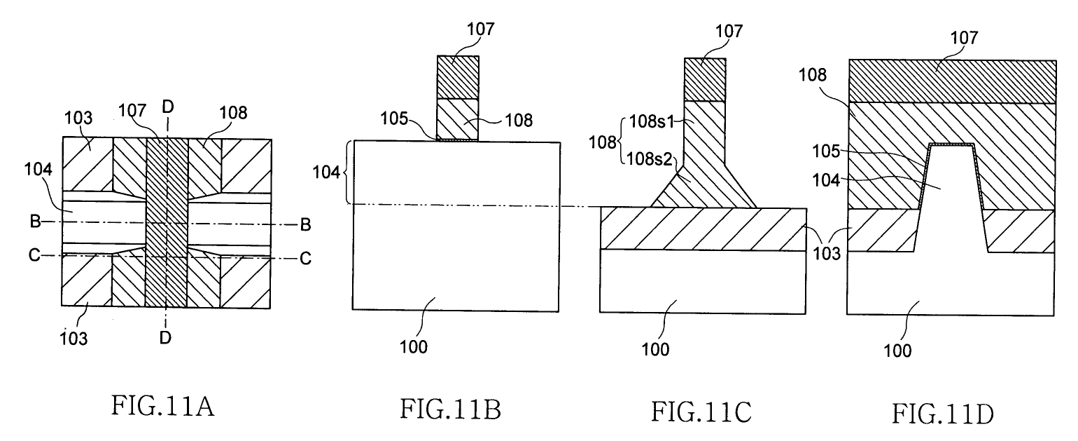

At a second step, the remaining DOPOS film 106 is etched. Dry etching at the second step utilizes the same mixed gas of HBr gas, O₂ gas, and SF₆ gas as that of the first step. At the second step, however, dry etching is performed by increasing O₂ gas by about 15 to 35% as compared to the first step. By slightly increasing O₂ gas, as shown in FIGS. 11A to 11D, the DOPOS film 106 is etched not vertically but in a tapered manner at the second step.

By etching the DOPOS film 106 at the first and second steps, as shown in FIG. 11C, a gate electrode 108 that has a non-tapered portion 108s1 and a tapered portion 108s2 that correspond substantially to the non-tapered portion 14s1 and the tapered portion 14s2, respectively of the side surface covering portion 14s shown in FIG. 2B is formed.

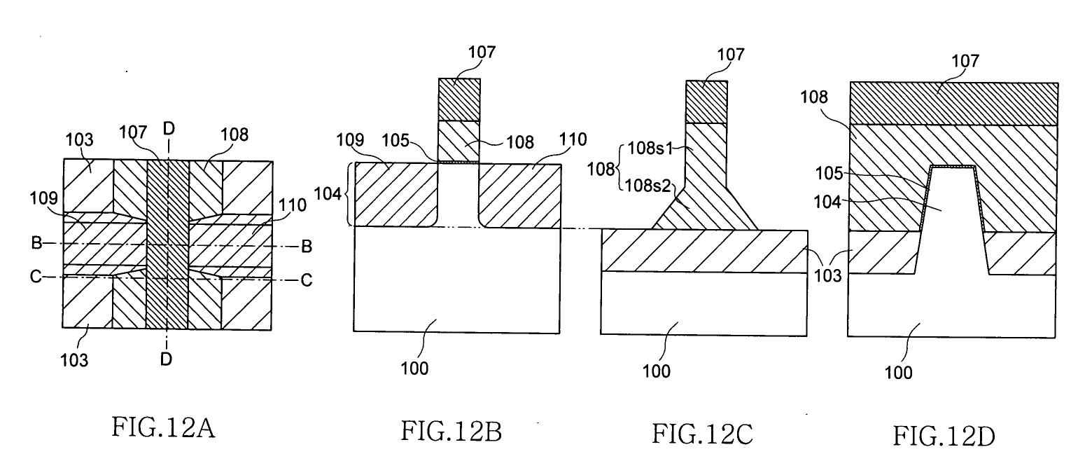

Ion implantation is then performed in a direction vertical to semiconductor substrate 100 by using the gate electrode 108 as a mask. As shown in FIGS. 12A to 12D, a source region 109 and a drain region 110 are formed and a fin field effect transistor is completed.

As described above, according to the manufacturing method of the first embodiment, the gate electrode 108 with the non-tapered portion 108s1 and the tapered portion 108s2 is provided by simply changing the etching gas during the patterning of the DOPOS film 106.

A second embodiment of the present invention is described below. The second embodiment is different from the first embodiment in the shape of the gate electrode.

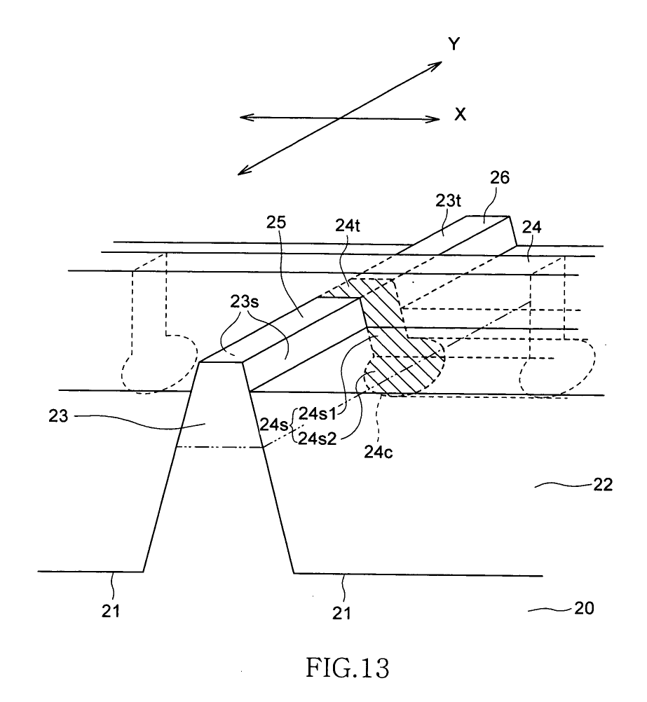

FIG. 13 is a schematic perspective view showing the configuration of a semiconductor device according to the second embodiment.

As shown in FIG. 13, the semiconductor device according to the second embodiment has a semiconductor substrate 20, a trench 21 formed in the semiconductor substrate 20, and an STI 22 provided at the bottom of the trench 21. The STI 22 is embedded in the trench 21 from the bottom to the middle of the trench.

Unlike the first embodiment, in the second embodiment, a part of the semiconductor substrate with a predetermined depth from the surface of the STI 22 to the two-dot chain line in FIG. 13 as well as a fin portion which is a part of the semiconductor substrate protruding from the STI 22 serves as a fin active region 23. The fin active region 23 extends in the Y direction shown in FIG. 13 and has a top surface 23t and two side surfaces 23s. The side surfaces 23s of the fin active region 23 are in the same planes as those of the STI 22. As shown in FIG. 13, as the side surfaces 23s of the fin active region 23 are tapered, the cross-section of the fin active region 23 is formed in a trapezoidal shape. The cross-section of the fin active region 23 means a cross-section along the X direction shown in FIG. 13. Such a configuration of the fin active region 23 is provided because the fin active region 23 and the trench 21 are formed in the same process as in the first embodiment.

As described above, as the cross-section of the fin active region 23 is trapezoidal, the X direction width of the fin active region 23 is narrower toward its top and wider toward its bottom.

The semiconductor device according to the second embodiment has a gate electrode 24 that extends in the X direction so as to cross the fin active region 23. Accordingly, parts of the side surfaces 23s and the top surface 23t of the fin active region 23 are covered by the gate electrode 24. In the second embodiment, a part of the gate electrode 24 is embedded in the STI 22. In the fin active region 23, a source region 25 and a drain region 26 that sandwich the gate electrode 24 are formed to a depth indicated by the two-dot chain line. A fin field effect transistor is thus configured.

As shown in FIG. 13, the Y direction width of upper part of the gate electrode 24 above the STI 22 is substantially fixed. Meanwhile, the lower part of the gate electrode 24 embedded in the STI 22 has an elliptical portion 24c with an elliptical cross-section in the Y direction. Specifically, the inner side surface of the gate electrode 24 has a side surface covering portion 24s covering a part of the side surface 23s of the fin active region 23 and a top surface covering portion 24t covering a part of the top surface 23t as indicated by hatchings in FIG. 13.

The side surface covering portion 24s of the gate electrode 24 has a straight portion 24s1 with substantially fixed Y direction width and a semi-elliptical portion (a part of elliptical portion 24c above the two-dot chain line) 24s2, i.e., a part of the elliptical portion 24c overlapping the fin active region 23. The Y direction width of the straight portion 24s1 coincides substantially with that of the top surface covering portion 24t. According to the present invention, the term “elliptical” includes the term “circular”.

In the straight portion 24s1, the Y direction width of the gate electrode 24 is fixed independently of the X direction width of the fin active region 23. In the semi-elliptical portion 24s2, the wider the X direction width of the fin active region 23 becomes, the wider the Y direction width of the gate electrode 24. At the bottom of the fin active region 23, although the X direction width of the fin active region 23 is increased, the Y direction width of the gate electrode 24 is increased correspondingly. Therefore, control of electric field by the gate electrode 24 is improved. As a result, punch-through between the source region 25 and the drain region 26 is suppressed. The semi-elliptical portion 24s2 of the second embodiment corresponds to the tapered portion 14s2 of the side surface covering portion 14s shown in FIG. 2 according to the first embodiment. Accordingly, substantially the same effects as those in the first embodiment can thus be attained.

Further, on the top surface 23t of the fin active region 23, the gate electrode 24 is narrow, i.e., has substantially the same width as that of upper part of the side surface covering portion 24s. A short margin between the gate electrode 24 and a source contact or a drain contact (not shown) formed on the both adjacent sides of the gate electrode 24 is sufficiently ensured.

The method for forming the source region 25 and the drain region 26 according to the second embodiment is substantially the same as in the first embodiment with reference to FIG. 3 except that ion implantation is performed not to the level of the surface of the STI 22 but to the depth of the fin active region 23 in FIG. 13 (indicated by the two-dot chain line). The effects of the second embodiment are substantially the same as in the first embodiment. Therefore, descriptions thereof will be omitted.

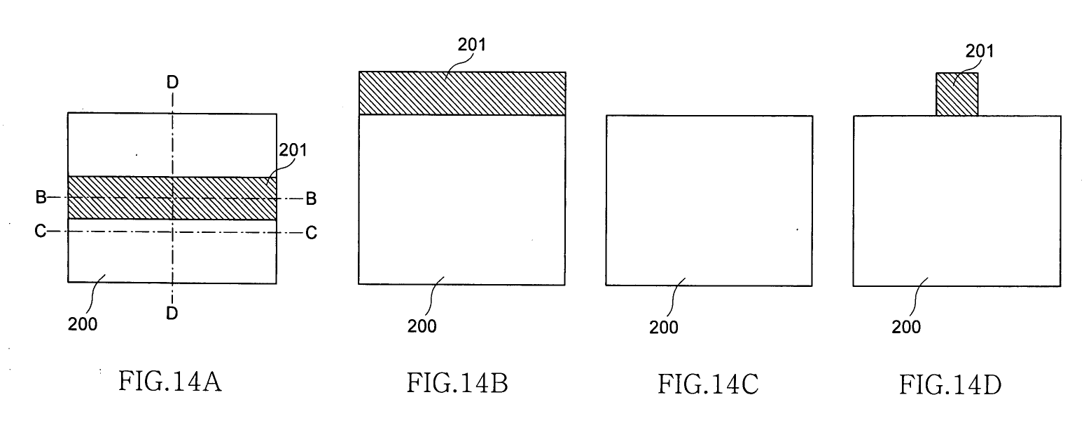

A method for manufacturing the semiconductor device according to the second embodiment is described next with reference to FIGS. 14A to 26D. In FIGS. 14A to 26D, the drawings with alphabetical letter A attached with their respective numbers are top views, and the drawings with alphabetical letters B, C, and D attached with their respective numbers are cross-sectional views along the lines B-B, C-C, and D-D, respectively. The line D-D corresponds to the X direction in FIG. 13, while the lines B-B and C-C the Y direction in FIG. 13.

First, as shown in FIGS. 14A to 14D, a hard mask 201 that is made of silicon nitride and covers an area on a semiconductor substrate 200 which is to be a fin active region is formed.

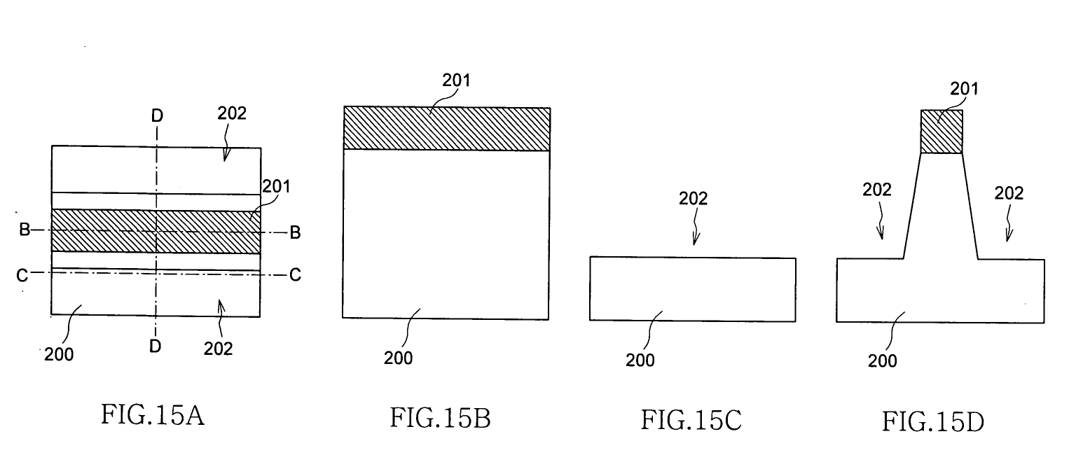

Next, as shown in FIGS. 15A to 15D, the semiconductor substrate 200 is etched using the hard mask 201 to form a trench 202 with a depth of, e.g., about 250 nm.

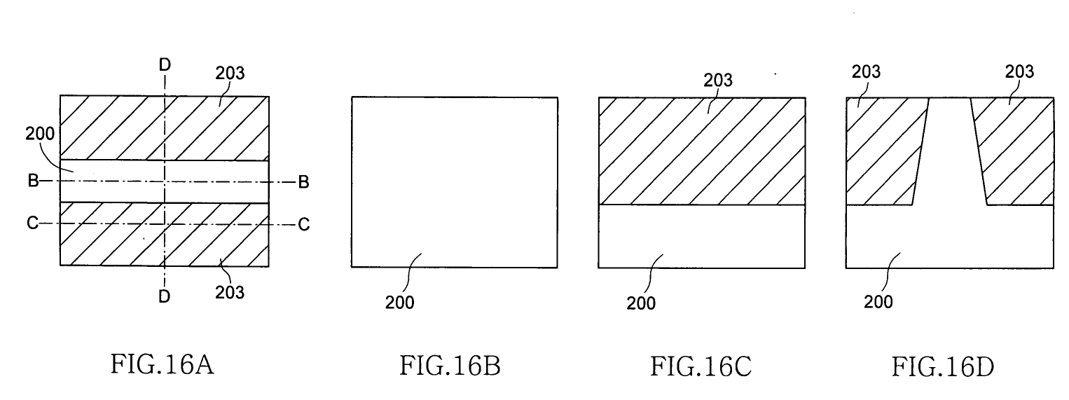

Silicon oxide is then applied entirely, and the silicon oxide on the top of the substrate is removed by wet etching. As shown in FIGS. 16A to 16D, an STI 203 whose surface is at the same level as that of the semiconductor substrate 200, i.e., which has a thickness of about 250 nm is embedded in the trench 202.

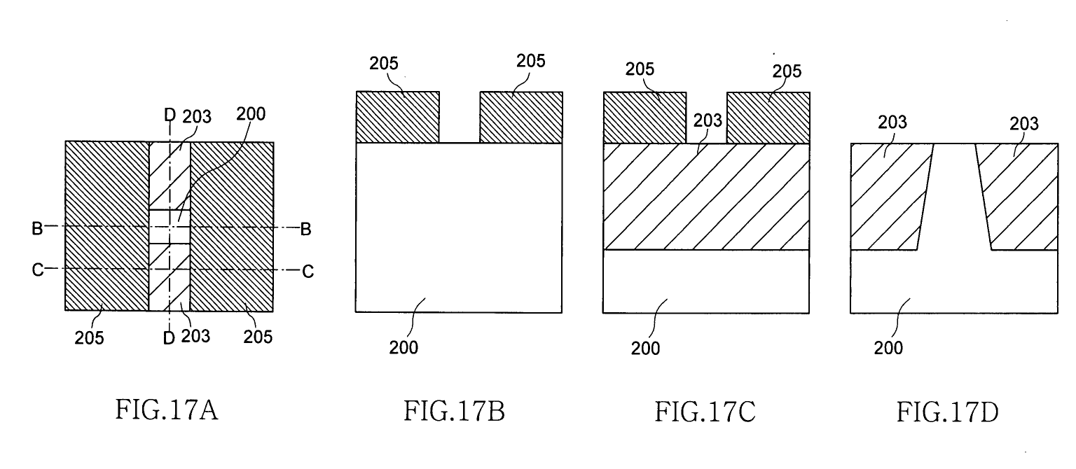

Next, as shown in FIGS. 17A to 17D, a hard mask 205 is formed that is made of silicon nitride with a thickness of about 120 nm and has a slit opening with a width of about 100 nm in a direction perpendicular to the direction the STI 203 extends.

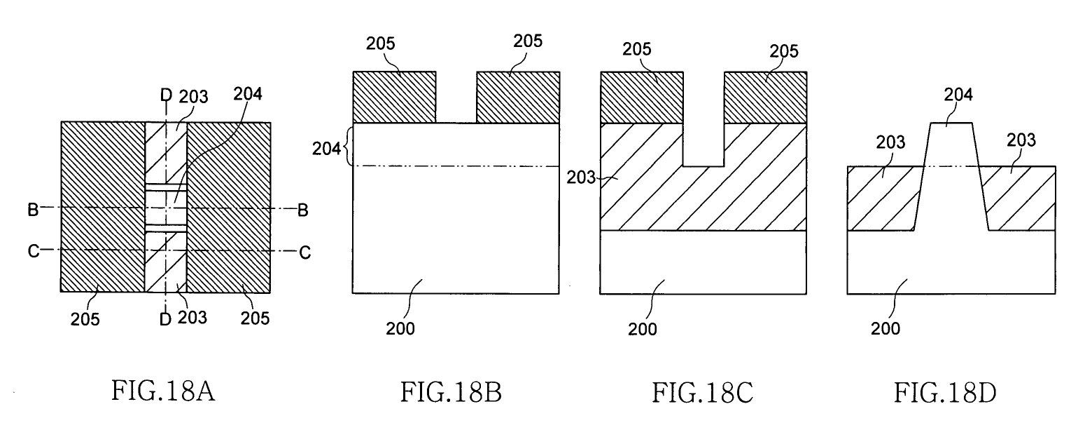

The STI 203 made of silicon oxide is then etched about 100 nm using the hard mask 205. As shown in FIGS. 18A to 18D, a fin active region 204 is thus formed.

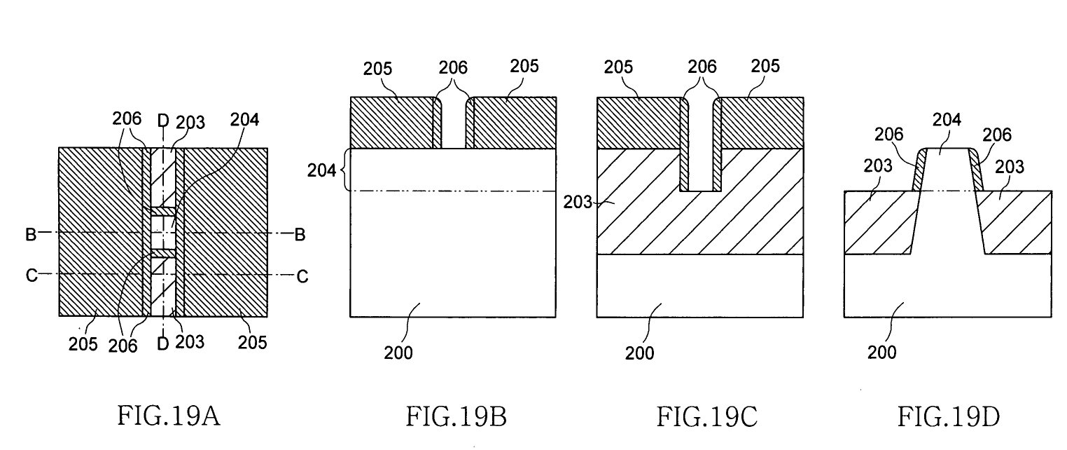

Next, silicon nitride is applied entirely to a thickness of about 20 nm and then etched back. As shown in FIGS. 19A to 19D, aside wall 206 made of silicon nitride with a thickness of about 20 nm is formed at the inner side surfaces of slit openings of the hard mask 205 and the underlying STI 203 and at the side surfaces of the fin active region 204.

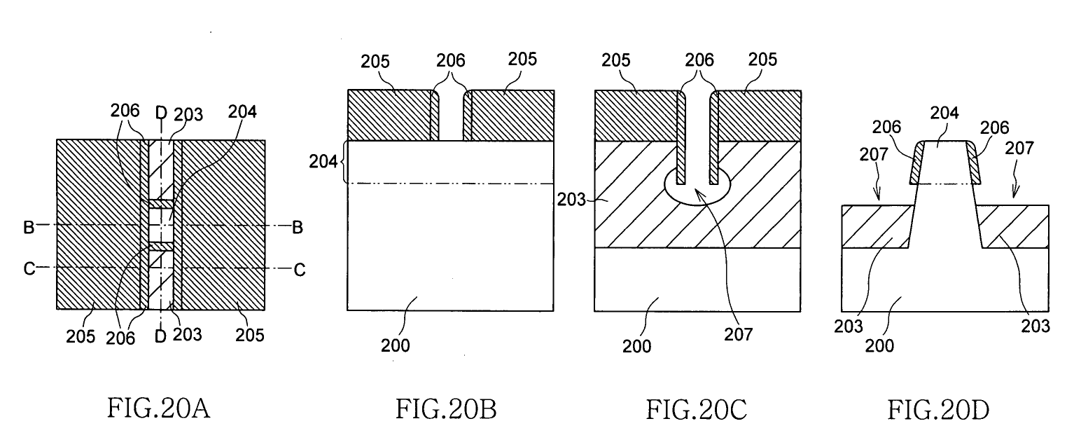

As shown in FIGS. 20A to 20D, isotropic etching is then performed upon the STI 203 made of silicon oxide (e.g., about 50 nm) using the hard mask 205 and the side wall 206 as a mask. As shown in FIG. 20C, a groove 207 with an elliptical cross-section is formed.

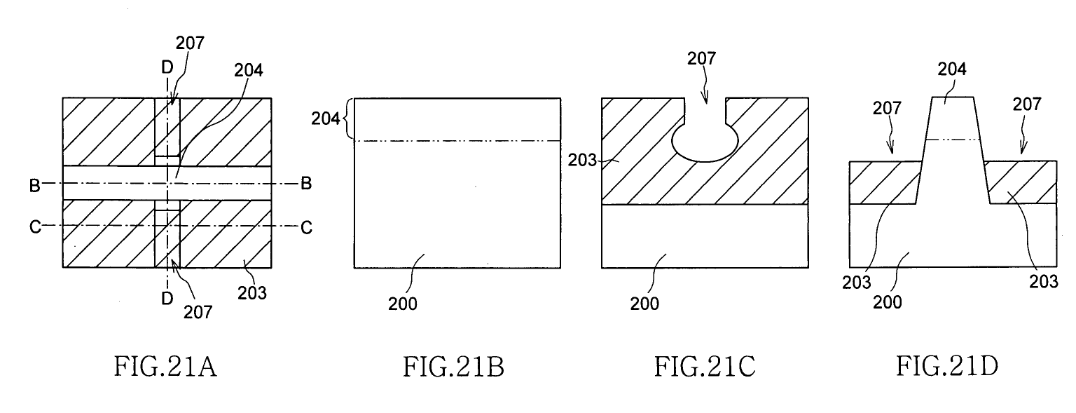

As shown in FIGS. 21A to 21D, the hard mask 205 and the side wall 206 are then removed by etching.

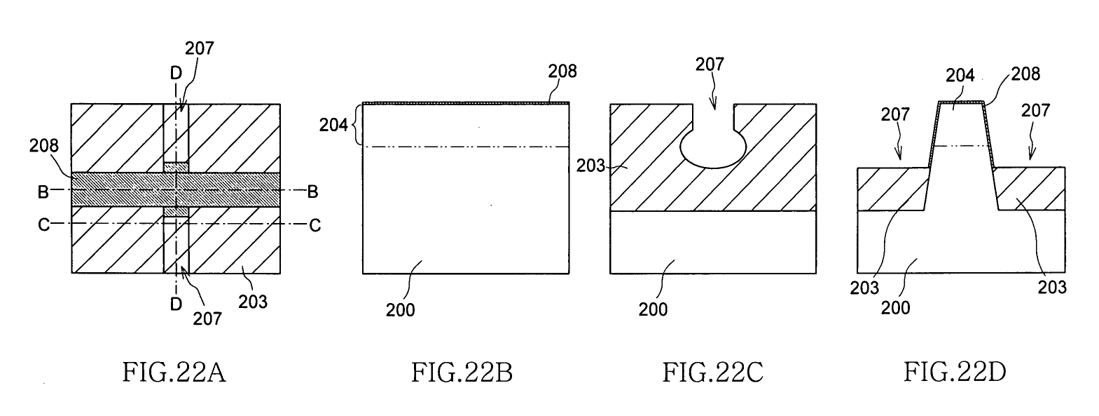

As shown in FIGS. 22A to 22D, a gate insulating film 208 is formed on the top surface of the fin active region 204 and the side surface of the fin active region 204 exposed to the groove 207.

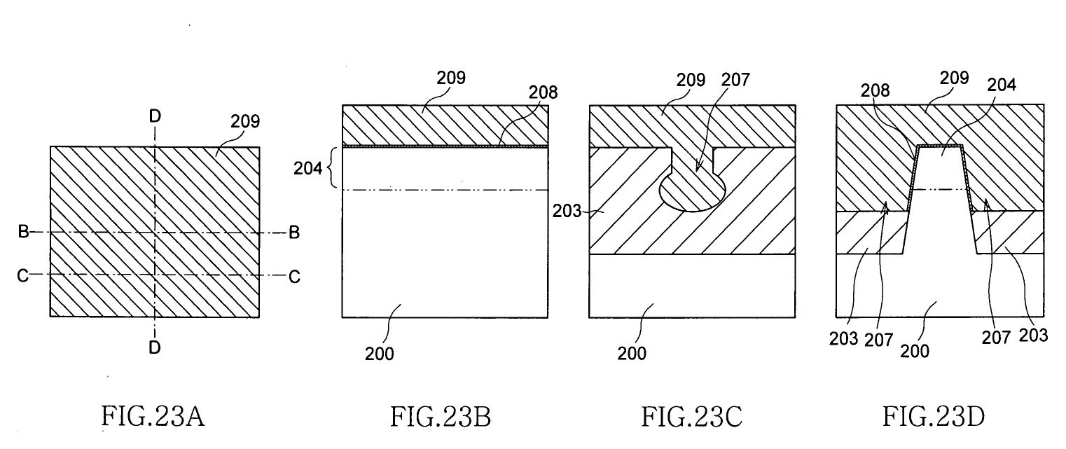

As shown in FIGS. 23A to 23D, a DOPOS film 209 is then applied entirely so as to be embedded in the groove 207, so that its thickness on the gate insulating film 208 is about 100 nm.

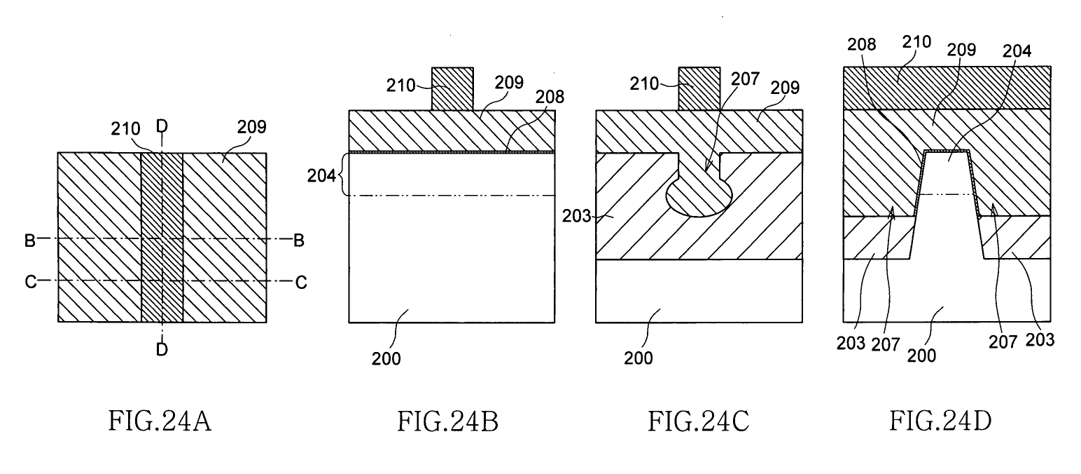

As shown in FIGS. 24A to 24D, a hard mask 210 that is made of silicon nitride and has a width of about 100 nm is then formed on the DOPOS film 209 for making a gate electrode.

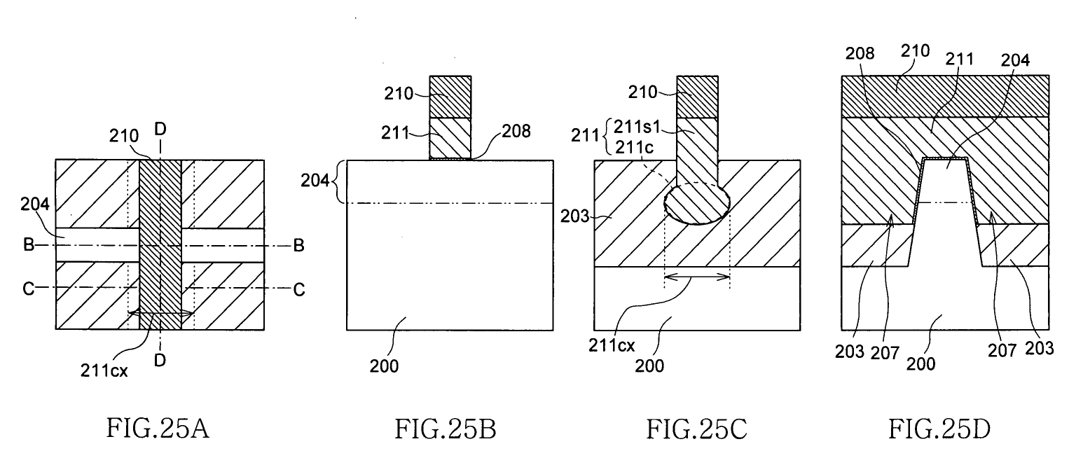

Next, as shown in FIGS. 25A to 25D, the DOPOS film 209 is dry etched in the pattern of the gate electrode by using the hard mask 210. The cross-section of a gate electrode 211 along the line C-C includes an elliptical portion 211c and a straight portion 211s1 which is made on the elliptical portion 211c and has a width narrower than the maximum width 211cx of the elliptical portion 211c.

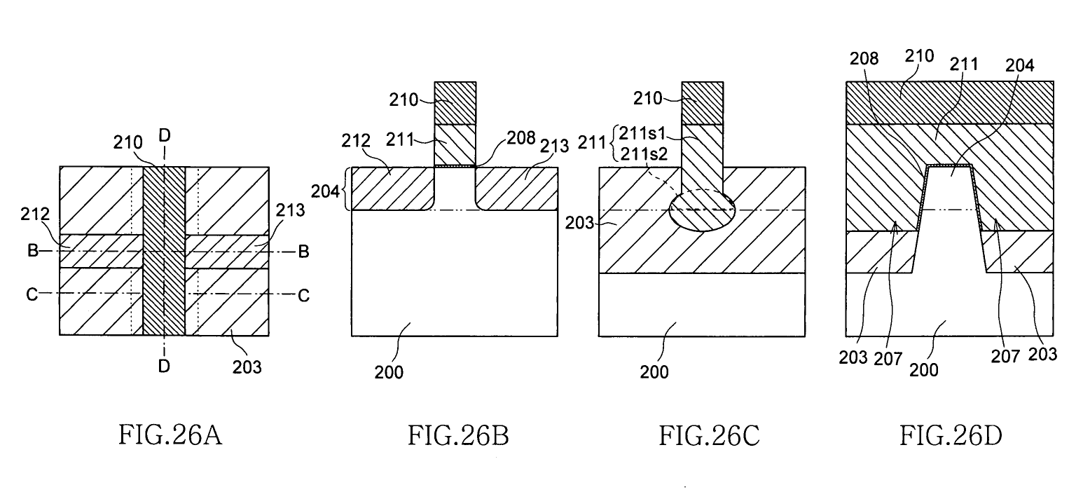

Ion implantation is then performed in a direction vertical to the semiconductor substrate 200 by using the gate electrode 211 as a mask, so that a source region 212 and a drain region 213 are formed as shown in FIGS. 26A to 26D. A fin field effect transistor is thus completed. The bottoms of the source region 212 and the drain region 213 are placed at substantially the same depth as the depth obtained when the width of the elliptical portion 211c of the gate electrode 211 is maximized (the bottom of the fin active region 204).

The source region 212 and the drain region 213 are formed as described above. On the side surface of the fin active region 204, the electric field is controlled by a semi-elliptical portion 211s2 which is the upper half of the elliptical portion 211c of the gate electrode 211 and the straight portion 211s1 made on the semi-elliptical portion 211s2. That is, the gate electrode 211 has the straight portion 211s1 corresponding to the straight portion 24s1 of the side surface covering portion 24s shown in FIG. 13 and the semi-elliptical portion 211s2 corresponding to the semi-elliptical portion 24s2 of the side surface covering portion 24s shown in FIG. 13.

As described above, according to the second embodiment, the semiconductor device shown in FIG. 13 can be prepared easily without a difficult process for adjusting the amount of etching gas with high precision as in the first embodiment.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

In the above embodiments, regarding the gate electrode covering the side surface of the fin active region (side surface covering portion), the upper non-tapered part, lower tapered part, upper straight part, and lower semi-elliptical part have been described. However, the prevent invention is not limited to such parts. For example, the side surface covering portion can be formed in a tapered shape from its top to bottom end (i.e., in a trapezoidal shape) without any non-tapered portion (or straight portion). Alternatively, the side surface covering portion can be formed so that its upper part is made in a quadrangular shape with narrow width and its lower part is made in a quadrangular shape with wide width (i.e., formed in a convex shape).

According to the manufacturing methods of the above embodiments, the source and drain regions are formed by performing ion implantation in a direction vertical to the semiconductor substrate. Ion implantation can be performed in an oblique direction to the semiconductor substrate as shown in FIG. 3B.

What is claimed is:

1. A semiconductor device comprising:
a fin active region having a tapered side surface;
a gate electrode that has a side surface covering portion covering a part of the side surface of the fin active region and a top surface covering portion covering a part of a top surface of the fin active region; and
a source region and a drain region formed in the fin active region, wherein
a width of at least a part of the side surface covering portion of the gate electrode is wider at its relatively lower part than at its relatively upper part.

2. The semiconductor device as claimed in claim 1, wherein a cross-section of the fin active region is formed in a trapezoidal shape.

3. The semiconductor device as claimed in claim 1, wherein the side surface covering portion of the gate electrode has a tapered portion whose width becomes wider from its top to its bottom.

4. The semiconductor device as claimed in claim 3, wherein the side surface covering portion of the gate electrode further has an non-tapered portion located above the tapered portion whose width coincides substantially with a width of the top surface covering portion.

5. The semiconductor device as claimed in claim 1, wherein the side surface covering portion of the gate electrode has a semi-elliptical portion.

6. The semiconductor device as claimed in claim 5, wherein the side surface covering portion of the gate electrode further has an non-tapered portion located above the semi-elliptical portion whose width coincides substantially with a width of the top surface covering portion.

7. The semiconductor device as claimed in claim 1, wherein a distance between the source region and the drain region coincides substantially with the width of the top surface covering portion over from the top to the bottom of the fin active region.

8. The semiconductor device as claimed in claim 1, wherein at least a part of a distance between the source region and the drain region is longer at relatively lower part of the fin active region than at relatively upper part of the fin active region.

9. A semiconductor device comprising:
a fin active region having a tapered side surface;
a gate electrode that has a side surface covering portion covering a part of the side surface of the fin active region and a top surface covering portion covering a part of a top surface of the fin active region; and
a source region and a drain region formed in the fin active region, wherein
wherein at least a part of a distance between the source region and the drain region is longer at relatively lower part of the fin active region than at relatively upper part of the fin active region.

10. The semiconductor device as claimed in claim 9, wherein a cross-section of the fin active region is formed in a trapezoidal shape.

11. A method for manufacturing a semiconductor device comprising steps of:
forming a fin active region with a tapered cross-section;
forming a gate electrode that has a side surface covering portion covering a part of the side surface of the fin active region and a top surface covering portion covering a part of a top surface of the fin active region; and
performing ion implantation into the fin active region using the gate electrode as a mask to form a source region and a drain region in the fin active region, wherein
the gate electrode is formed so that at least a part of the side surface covering portion has a wider width at its relatively lower part than at its relatively upper part.

12. The method for manufacturing a semiconductor device as claimed in claim 11, wherein the side surface covering portion of the gate electrode has a tapered portion whose width becomes wider from its top to its bottom.

13. The method for manufacturing a semiconductor device as claimed in claim 12, wherein the side surface covering portion of the gate electrode further has a non-tapered portion located above the tapered portion whose width coincides substantially with the width of a top surface covering portion.

14. The method for manufacturing a semiconductor device as claimed in claim 11, wherein the side surface covering portion of the gate electrode has a semi-elliptical portion.

15. The method for manufacturing a semiconductor device as claimed in claim 14, wherein the side surface covering portion of the gate electrode further has a non-tapered portion located above the semi-elliptical portion whose width coincides substantially with the width of the top surface covering portion.

16. The method for manufacturing a semiconductor device as claimed in claim 11, wherein a distance between the source region and the drain region coincides substantially with the width of the top surface covering portion over from the top to the bottom of the fin active region.

17. The method for manufacturing a semiconductor device as claimed in claim 16, wherein the source region and the drain region are formed by performing ion implantation in a direction perpendicular to a semiconductor substrate.

18. The method for manufacturing a semiconductor device as claimed in claim 11, wherein at least a part of a distance between the source region and the drain region is longer at relatively lower part of the fin active region than at relatively upper part of the fin active region.

19. The method for manufacturing a semiconductor device as claimed in claim 18, wherein the source region and the drain region are formed by performing ion implantation in an oblique direction to a semiconductor substrate.
